(19) United States
(12) Patent Application Publication
(10) Pub. No.: US 2004/0193986 A1
(43) Pub. Date: Sep. 30, 2004

(54) On-die pattern generator for high speed serial interconnect built-in self test

(76) Inventors: Karthisha S. Canagasaby, Santa Clara, CA (US); Victor W. Lee, San Jose, CA (US); Jay J. Nejedlo, Wilsonville, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/404,622

(22) Filed: Mar. 31, 2003

(51) Int. Cl. G01R 31/28

(52) U.S. Cl. 714/738

(57) ABSTRACT

An apparatus and method for generating test patterns with an on-die self test circuit (e.g., IBIST) are disclosed. In various embodiments, the IBIST comprises a sub-pattern generator that may include one or more of a storage element for a user-defined sub-pattern, a clock sub-pattern generator, and a constant sub-pattern generator. A multiplexer is used to assemble a test pattern based on a combination of sub-patterns from the sub-pattern generator.

### FIELD

The embodiments disclosed herein relate generally to testing interconnect links IO (e.g., input/output) links, and more particularly to on-die interconnect testers.

### BACKGROUND

As the speed of computer processors increases, the speed of the data transfer links (e.g., IO links) in the system must also increase in order to avoid having the peripheral components, which are connected to the system by the data transfer links, become a bottleneck that slows system performance. Once these faster data transfer links are created, they must be tested in a variety of operating conditions in order to test the integrity of the links. For example, test patterns can be sent over the links to test functionality or how each link operates under various temperature and voltage conditions.

Several different methods have been used in the past to test IO links. For example, stand-alone testers (e.g., not part of the component being tested) have been previously used to test IO links. However, stand-alone testers are currently too slow and cannot perform tests at the top speeds of current devices. For example, some processors can run at 3 Gigahertz or faster, which is beyond the capabilities of even the fastest stand-alone tester.

Due to the shortcomings of stand-alone testers, on-die (e.g., part of the component to be tested) testers have been developed that are each specifically designed for a certain IO link (e.g., PCI Express (“Peripheral Component Interconnect”)). However, the pattern generators that are part of these protocol-specific on-die testers are not re-usable with other HSI (e.g., high speed IO) protocols.

### DESCRIPTION OF THE DRAWINGS

Various embodiments are illustrated by way of example and not by way of limitation in the figures of the accompanying drawings in which like references indicate similar elements. It should be noted that references to “an,” “one,” “the,” “other,” “alternative,” or “various” embodiments in this disclosure are not necessarily to the same embodiment, and such references mean at least one.

FIG. 1 is a flow chart of one embodiment of a method for testing a circuit with an on-die self tester.

FIG. 2 is one embodiment of a sample test pattern that can be generated with the various testers disclosed herein.

FIG. 3 is an embodiment of a control register used to generate a test pattern.

FIG. 4 is an embodiment of a control register used to dictate the number of times a test inter-pattern is included in the test pattern.

FIG. 5 is a block diagram of a pattern generator capable of combining a user-defined sub-pattern with at least one of a clock sub-pattern and a constant sub-pattern.

FIG. 6 is a system including the pattern generator of FIG. 5.

FIG. 7 shows a testing station coupled to the system shown in FIG. 6.

### DETAILED DESCRIPTION

In the following description, for the purposes of explanation, numerous specific details are set forth in order to provide a thorough understanding of the various embodiments. It will be apparent to one skilled in the art that the embodiments may be practiced without some of these specific details. In other instances, certain structures and devices are omitted or simplified in order to avoid obscuring the details of the various embodiments. For example, various signals, layout patterns and logical circuits may be modified according to the teachings of the various embodiments.

The following description and the accompanying drawings provide examples for the purposes of illustration. However, these examples should not be construed in a limiting sense as they are not intended to provide an exhaustive list of all possible implementations.

Various methods disclosed herein can be implemented by using a machine to read instructions stored on a machine-readable medium and to perform functions in accordance with those instructions. A machine-readable medium includes any mechanism that provides (e.g., stores and/or transmits) information in a form readable by a machine (e.g., a computer). For example, a machine-readable medium includes read only memory (“ROM”); random access memory (“RAM”); magnetic disk storage media; optical storage media; flash memory devices; and electrical, optical, acoustical or other forms of propagated signals (e.g., carrier waves, infrared signals, and digital signals).

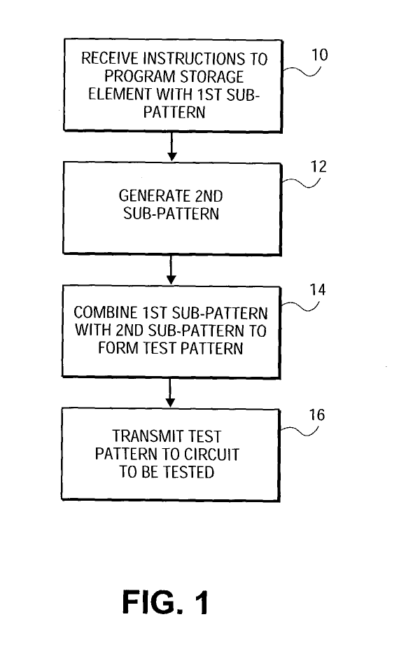

Referring now to FIG. 1, a flow chart is shown for one embodiment of a method for testing a circuit (e.g., HSI link) with an on-die self test circuit such as an IBIST (e.g., Interconnect Built In Self Test). At block 10, instructions are received to program a storage element with a first sub-pattern. In various embodiments, the first sub-pattern is a user-defined sub-pattern that is received from a testing station coupled to the IBIST.

A second, different sub-pattern is generated at block 12. Generation of the second sub-pattern may include generating a clock sub-pattern and/or a constant sub-pattern. In an alternative embodiment, the sub-pattern generator comprises at least one of a clock pattern generator, a constant pattern generator and a user-programmable sub-pattern storage element. As described below, a multiplexer may be used to combine sub-patterns from the sub-pattern generator to form a test pattern.

At block 14, the second sub-pattern is combined with the first sub-pattern to form a test pattern. The resultant test pattern is transmitted to a circuit to be tested, at block 16. The transmission shown at block 16 may include sending the test pattern to an IO buffer circuit.

In various embodiments, the circuit to be tested can be, for example, any type of IO link or data transfer circuit. Besides testing, the embodiments disclosed herein may also be used in system level debug and design validation.

Although not shown in FIG. 1, the method may further include generation of a start delimiter and/or an end delimiter, which are added to the test pattern to indicate the beginning and ending of the test pattern. The method may also include controlling generation of the test pattern with a programmable control register. The control register is included to indicate the length and position of each of the sub-patterns within the test pattern.

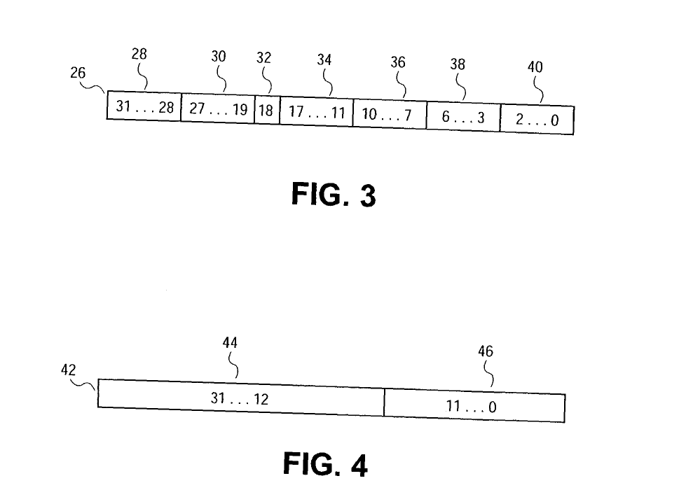

In various embodiments, controlling generation of the test pattern includes programming a field of the control register to indicate the number of times each sub-pattern should be included in a test inter-pattern (e.g., sub-pattern loop counter) and/or programming a field of the control register to indicate the number of times the test inter-pattern should be included in the test pattern (e.g., test pattern loop counter). The control registers are discussed in more detail below in connection with FIGS. 3 and 4.

As used herein, a test “inter-pattern” is a combination of “sub-patterns.” Likewise, a test pattern may be comprised of test inter-patterns. However, there is no requirement that the test pattern is comprised of inter-patterns. Rather, the test pattern may be comprised solely of sub-patterns or a combination of sub-patterns and inter-patterns.

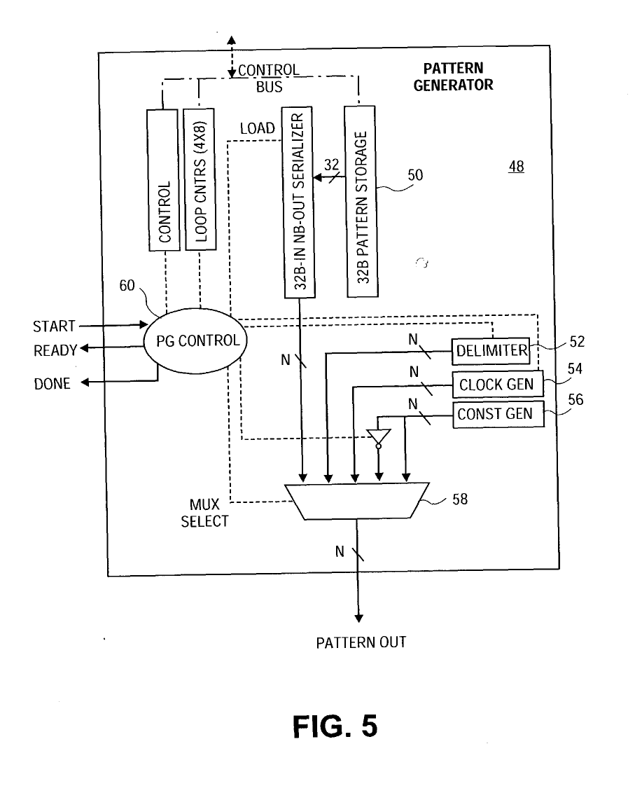

The method described above can be performed by, for example, the pattern generator represented by the block diagram of FIG. 5. In the embodiment shown, pattern generator 48 includes user-programmable sub-pattern storage element 50. Although storage element 50 is shown as a 32-bit storage element, other sizes (e.g., 64 bits) are within the scope of the embodiments described herein.

Pattern generator 48 also includes delimiter generator 52 to generate start delimiters and end delimiters, as necessary. Clock pattern generator 54 is capable of generating a clock sub-pattern that can be included in the test pattern. Constant pattern generator 56 can generate a constant value, which may be added to the test pattern as dictated by the control registers shown, for example, in FIGS. 3 and 4. PG Control 60 contains control logic to control generation of the delimiters and various sub-patterns and assembly of the test pattern. As discussed above, the test pattern is transmitted to the circuit (e.g., IO link) to be tested. Pattern generator 48 outputs the test pattern in N-bit chunks, where N is the input granularity of the HSI interface.

As indicated by the control registers, multiplexer 58 is capable of combining the user-defined (e.g., user-programmable) sub-pattern with one or more of the sub-patterns generated by delimiter generator 52, clock generator 54, and constant generator 56. Specifically, the control register(s) control generation of the test pattern by indicating the length and position of each of the sub-patterns within the test pattern.

For example, FIG. 3 shows control register 26, which is one embodiment of a 32-bit control register that can be used to generate a test pattern. Control register 26 includes a number of fields 28-40 that can be used to indicate how the test pattern should be assembled. For example, field 40 includes bits 0-2 and is used to indicate sub-pattern ordering within a test inter-pattern (e.g., user-defined sub-pattern+clock sub-pattern+constant sub-pattern, or user-defined sub-pattern+constant sub-pattern+clock sub-pattern).

Field 38 includes bits 3-6 and indicates the number of times the user-defined sub-pattern should be included (e.g., loop counter) in the test inter-pattern. Field 36 includes bits 7-10 and indicates the clock pattern period to be used (e.g., some fraction of the link data rate). Field 34 includes bits 11-17 and indicates the number of periods the clock sub-pattern should be generated.

Field 32 includes bit 18 and indicates whether the constant generator should generate a constant “1” or a constant “0.” Field 30 includes bits 19-27 and indicates the length of constant to be generated (e.g., number of bits). Field 28 includes bits 28-31, which are reserved.

FIG. 4 shows a 32-bit control register that can be used as a test inter-pattern loop counter. Specifically, control register 42 includes fields 44 and 46. Field 46 includes bits 0-11, which indicate how many times the test inter-pattern, as defined in field 40 of FIG. 3, should be included in the test pattern. Although register 42 of FIG. 4 and register 26 of FIG. 3 are shown as separate registers, they may be combined into a single register in an alternative embodiment. Likewise, the number, size, and arrangement of the fields used may be altered.

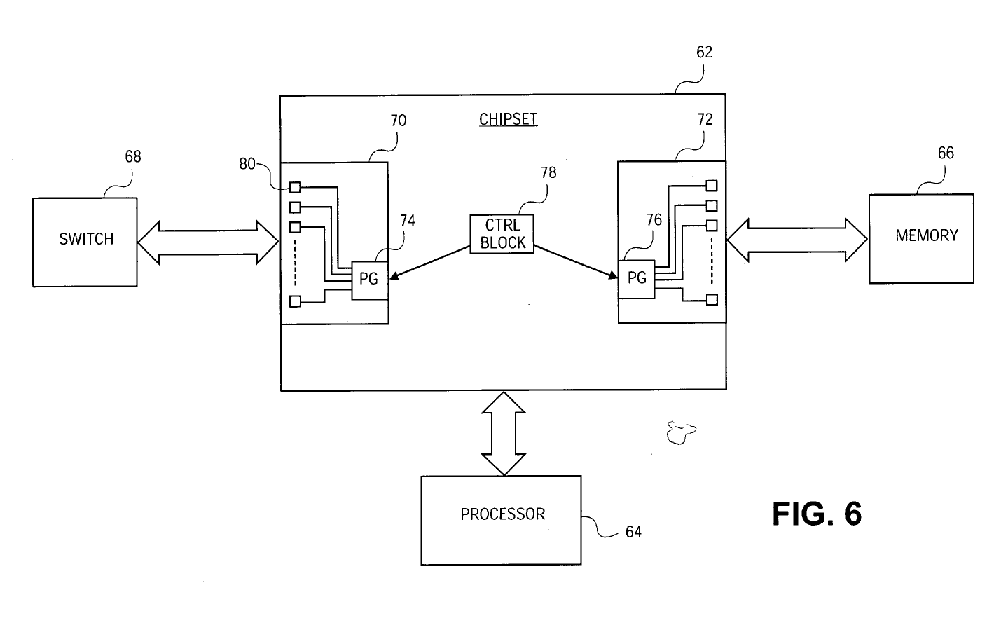

In various embodiments, the control registers are located in the control block (See FIG. 6). However, the control registers may be located elsewhere in alternative embodiments.

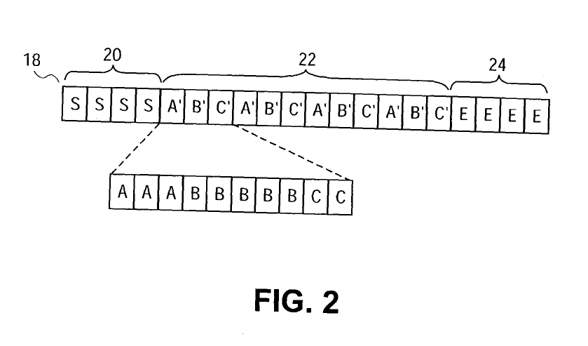

FIG. 2 depicts one complete test pattern generated according to the embodiments disclosed herein. Specifically, test pattern 18 includes four 8-bit start delimiters 20, four test inter-patterns 22, and four 8-bit end delimiters 24. Each inter-pattern 22, although represented by “A′B′C′,” is actually comprised of the pattern “AAABBBBBCC.” In operation, pattern generator 74 of FIG. 6, which is the same as pattern generator 48 of FIG. 5, can be used to generate test pattern 18 in the following manner.

First, control block 78 of FIG. 6 instructs pattern generator 74 to output four 8-bit start delimiters 20. When the first start delimiter is output, pattern generator 74 asserts the “Ready” signal to trigger transmitter blocks 80 to patch in test pattern 18 for transmission (e.g., to switch 68). Pattern generator 74 then begins to generate test inter-patterns 22.

In this regard, FIG. 2 shows that each inter-pattern 22 is comprised of three instances of the user-defined sub-pattern (“A”), followed by five instances of the clock sub-pattern (“B”), followed by two instances of the constant sub-pattern (“C”). Each of these sub-patterns is generated by their respective generator blocks, as controlled by control registers 26 and 42 of FIGS. 3 and 4, discussed above.

For example, field 40 of control register 26 would indicate that the sub-pattern ordering should be “ABC.” Field 38 (e.g., user-defined sub-pattern loop counter) would indicate that the user-defined sub-pattern should be included three times before adding the clock sub-pattern. Field 34 (e.g., clock sub-pattern loop counter) would indicate that the clock sub-pattern should be included five times before adding the constant sub-pattern. Field 30 (e.g., constant sub-pattern loop counter) would indicate that the constant sub-pattern should be included two times in order to complete the inter-pattern.

This entire sequence of test inter-pattern generation is repeated based on the value contained in field 46 (e.g., test inter-pattern loop counter) of control register 42. Thus, in the present example, field 46 would indicate that the test inter-pattern should be generated four times before adding end delimiters 24. Once the four end delimiters 24 are added, generation of test pattern 18 is complete, and pattern generator 74 sends the “Done” signal to control block 78.

The foregoing example relates to an IBIST mode, in which only one test pattern is generated before the system stops generation and transmission of test patterns. However, the system may also be set to run in a continuous mode, in which the pattern generator continues to repeatedly generate the same IBIST pattern until the user stops pattern generation (e.g., via a test station).

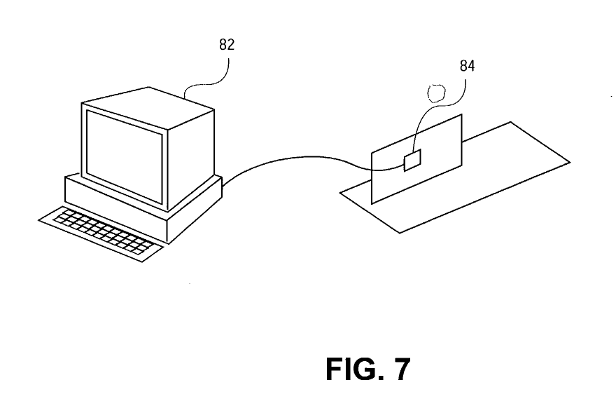

In various embodiments, a user can access the IBIST via a testing station in order to define the user-programmable sub-pattern. For example, testing station 82 of FIG. 7 is a computer. However, testing station 82 may be any device that allows the user to set the user-defined sub-pattern and control registers to generate the desired test pattern.

Testing station 82 is coupled to microelectronic device 84, which includes an HSI IBIST according to the various embodiments disclosed herein. The IBIST of microelectronic device 84 may be formed on a substrate, as shown in FIG. 7. Microelectronic device 84 may also include an interface port to be coupled to the testing station. The connection between the interface port and testing station 82 may be any suitable connection that permits communication of the instructions to perform test pattern generation, as described herein.

In addition to control block 78 and pattern generator 74, FIG. 6 shows a system comprising processor 64 (e.g., a first primary integrated circuit component), chipset 62 (e.g., a second primary integrated circuit component), memory 66, and switch 68. Port 70 of chipset 62 communicates with switch 68, and port 72 of chipset 62 communicates with memory 66. Other examples of primary integrated circuit components include, among others, an IO controller, a memory controller, and an agent.

Chipset 62 includes two IBISTs (e.g., pattern generator 74 and pattern generator 76). In this regard, only one control block 78 is required for chipset 62 since pattern generator 74 and pattern generator 76 are both compliant with the embodiments disclosed herein. However, if the two pattern generators were distinct (e.g., one of them was compliant with only one specific HSI protocol, such as PCI Express), then control block 78 would be co-located in the same port as the pattern generator that was compliant with the embodiments disclosed herein. Likewise, the single protocol pattern generator would require its own specific control block, co-located in its respective port, as well.

Port 70 comprises core function circuitry (e.g., transmitter blocks 80) coupled to an IO buffer to enable communication between processor 64 and switch 68 (e.g., a peripheral component). Switch 68 is also in communication with pattern generator 74 (e.g., IBIST) via an interconnect communications link.

Although only a simplified example of test pattern generation is shown above, the embodiments disclosed herein allow a user the flexibility to generate a vast number of test pattern types and sizes, without restriction as to the ordering of the various sub-patterns or a limitation to any specific HSI link protocol.

Some typical HSI IBIST test patterns that can be generated include, for example, a lone pulse, a differential common mode test pattern, cross-talk patterns, resonance patterns, and random patterns.

The lone pulse pattern is comprised of a long string of ones (or zeroes) followed by a single zero (or one) and repeated. If an HSI link is not 8-bit/10-bit encoded, the lone pulse pattern will accumulate ISI (e.g., intersymbol interference). ISI results in interference with the next symbol (e.g., signal distortion or loss) and is caused by high frequency transitions. For example, ISI can result in reduced amplitude and unwanted corruption of the pulse.

The lone pulse pattern can be used to test the functionality of a link to correctly receive the pattern. The same pattern can be used to measure signal integrity as a function of signal frequency and length of transmission (e.g. distance signal travels).

The differential common mode test patterns are patterns that initially build up common mode skew, using constant frequency patterns, followed by an ISI (as discussed above), and repeated. These patterns can be used sequentially with different frequency patterns in order to build up different common modes. One example of a differential common mode test pattern would be: 0101010101[10100111110101100000]1010101010. This example includes two complementary patterns (e.g., one before the brackets and one after the brackets) and an IBIST placed in the middle (e.g., in brackets).

There are no unique patterns to test cross-talk. Rather, any pattern can be used to test a channel (e.g., victim channel) by transmitting the same polarity (e.g., even mode) on surrounding channels (e.g., aggressor channels) or the opposite polarity (e.g., odd mode) on the surrounding channels. If the signal on the victim channel gets altered in either the odd mode or the even mode, the aggressor channels have corrupted the victim channel with cross-talk. Each channel can be sequentially tested as the victim channel with various aggressor channels operated in different modes to test the full range of operational integrity of the system.

Resonance patterns are ISI patterns that include a low frequency component that mimics power supply or package resonance. Due to the low frequency, the required pattern could be very long. Thus, not all IBIST implementations can provide resonance patterns for testing. Finally, random patterns are simply random combinations of signals used to test the system.

It is to be understood that even though numerous characteristics and advantages of various embodiments have been set forth in the foregoing description, together with details of structure and function of the various embodiments, this disclosure is illustrative only. Changes may be made in detail, especially matters of structure and management of parts, without departing from the scope of the various embodiments as expressed by the broad general meaning of the terms of the appended claims.

We claim:

1. An apparatus comprising:
a sub-pattern generator; and
a multiplexer capable of combining sub-patterns from the sub-pattern generator to form a test pattern.

2. The apparatus of claim 1, further comprising:
a delimiter generator to generate one of a start delimiter and an end delimiter that can be added to the test pattern by the multiplexer.

3. The apparatus of claim 2, wherein the delimiter generator is capable of generating a further one of a start delimiter and an end delimiter that can be added to the test pattern by the multiplexer.

4. The apparatus of claim 1, wherein the sub-pattern generator comprises:
one of a clock pattern generator, a constant pattern generator, and a user-programmable sub-pattern storage element.

5. The apparatus of claim 4, wherein the sub-pattern generator further comprises:
a further one of a clock pattern generator, a constant pattern generator, and a user-programmable sub-pattern storage element.

6. The apparatus of claim 1, further comprising:
a programmable control register to control generation of the test pattern by indicating the length and position of each of the sub-patterns within the test pattern.

7. The apparatus of claim 6, wherein the programmable control register comprises:
a field to indicate the number of times a sub-pattern should be included in a test inter-pattern; and
a field to indicate the number of times the test inter-pattern should be included in the test pattern.

8. A microelectronic device comprising:
a substrate;
a built-in self-test circuit formed on the substrate, wherein the circuit comprises
a user-programmable sub-pattern storage element,
a clock sub-pattern generator,
a constant sub-pattern generator, and
a multiplexer capable of combining a user-programmable sub-pattern with one of the clock sub-pattern and the constant sub-pattern to form a test pattern; and
core function circuitry coupled to an input/output buffer to enable communication between a primary integrated circuit component and a peripheral component in communication with the microelectronic device.

9. The microelectronic device of claim 8, further comprising:
a delimiter generator to generate one of a start delimiter and an end delimiter that can be added to the test pattern by the multiplexer.

10. The microelectronic device of claim 8, further comprising:
a programmable control register to control generation of the test pattern by indicating the length and position of each of the sub-patterns within the test pattern.

11. The microelectronic device of claim 10, wherein the programmable control register comprises:
a field to indicate the number of times a sub-pattern should be included in a test inter-pattern; and
a field to indicate the number of times the test inter-pattern should be included in the test pattern.

12. A method comprising:
receiving instructions to program a storage element with a first sub-pattern;
generating a second, different sub-pattern;
combining the first sub-pattern with the second sub-pattern to form a test pattern; and
transmitting the test pattern to a circuit to be tested.

13. The method of claim 12, wherein transmitting comprises:
sending the test pattern to an input/output buffer circuit.

14. The method of claim 12, further comprising:
generating one of a start delimiter and an end delimiter; and
adding the delimiter to the test pattern.

15. The method of claim 12, wherein generating a second sub-pattern comprises:
generating one of a clock sub-pattern and a constant sub-pattern.

16. The method of claim 12, further comprising:
controlling generation of the test pattern with a programmable control register, the control register to indicate the length and position of each of the sub-patterns within the test pattern.

17. The method of claim 16, wherein controlling comprises:
programming a field of the control register to indicate the number of times each sub-pattern should be included in a test inter-pattern; and
programming a field of the control register to indicate the number of times the test inter-pattern should be included in the test pattern.

18. A machine-readable medium containing instructions that, when executed by a machine, cause the machine to:
program a storage element with a first, user-defined sub-pattern;
generate a second, different sub-pattern;
combine the first sub-pattern with the second sub-pattern to form a test pattern; and
transmit the test pattern to a circuit to be tested.

19. The machine-readable medium of claim 18, wherein the instructions that cause the machine to transmit the test pattern comprise instructions that cause the machine to:
send the test pattern to an input/output buffer circuit.

20. The machine-readable medium of claim 18, further comprising instructions that cause the machine to:
generate one of a start delimiter and an end delimiter; and
add the delimiter to the test pattern.

21. The machine-readable medium of claim 18, wherein the instructions that cause the machine to generate a second sub-pattern comprise instructions that cause the machine to:
generate one of a clock sub-pattern and a constant sub-pattern.

22. The machine-readable medium of claim 18, further comprising instructions that cause the machine to:
control generation of the test pattern with a programmable control register, the control register to indicate the length and position of each of the sub-patterns within the test pattern.

23. The machine-readable medium of claim 22, wherein the instructions that cause the machine to control generation of the test pattern comprise instructions that cause the machine to:
program a field of the control register to indicate the number of times each sub-pattern should be included in a test inter-pattern; and
program a field of the control register to indicate the number of times the test inter-pattern should be included in the test pattern.

24. A system comprising:
a first primary integrated circuit component;
a second primary integrated circuit component coupled to the first primary integrated circuit component, wherein the second primary integrated circuit component comprises a built-in self-test circuit comprising
a user-programmable sub-pattern storage element,
a clock sub-pattern generator,
a constant sub-pattern generator, and
a multiplexer capable of combining the user-programmable sub-pattern with one of the clock sub-pattern and the constant sub-pattern to form a test pattern; and
a peripheral component coupled to the second primary integrated circuit component by an interconnect communications link.

25. The system of claim 24, wherein the chipset further comprises:
a delimiter generator to generate one of a start delimiter and an end delimiter that can be added to the test pattern by the multiplexer.

26. The system of claim 24, wherein the chipset further comprises:
a programmable control register to control generation of the test pattern, the control register having a field to indicate the number of times a sub-pattern should be included in a test inter-pattern and a field to indicate the number of times the test inter-pattern should be included in the test pattern.

27. The system of claim 24, further comprising:
a testing station that is accessible to a user, the testing station to enable the user to define the user-programmable sub-pattern.

28. The system of claim 27, wherein one of the first primary integrated circuit component and the second integrated circuit component comprise:
an interface port to be coupled to the testing station.
